(19) United States
(12) Patent Application Publication
(10) Pub. No.: US 2014/0165638 A1
(43) Pub. Date: Jun. 19, 2014

(54) COOLING DEVICE AND ELECTRONIC DEVICE MADE THEREWITH

(71) Applicants: Minoru Yoshikawa, Tokyo (JP); Hitoshi Sakamoto, Tokyo (JP); Akira Shoujiguchi, Tokyo (JP); Kenichi Inaba, Tokyo (JP); Arihiro Matsunaga, Tokyo (JP)

(72) Inventors: Minoru Yoshikawa, Tokyo (JP); Hitoshi Sakamoto, Tokyo (JP); Akira Shoujiguchi, Tokyo (JP); Kenichi Inaba, Tokyo (JP); Arihiro Matsunaga, Tokyo (JP)

(73) Assignee: NEC CORPORATION, Tokyo (JP)

(21) Appl. No.: 14/235,951

(22) PCT Filed: Jul. 20, 2012
(86) PCT No.: PCT/JP2012/069062

§ 371 Date: Jan. 29, 2014

(30) Foreign Application Priority Data
Aug. 1, 2011 (JP) 2011-168396

(51) Int. Cl. H05K 7/20

(52) U.S. Cl. CPC H05K 7/20309; H05K 7/20318
USPC 62/259.2; 62/513

(57) ABSTRACT

A cooling device employing a boiling cooling method cannot exhibit sufficient cooling performance when it is installed in a low-profile electronic device.

A cooling device of the present invention comprises an evaporation unit which contains a refrigerant, a condensation unit which performs heat radiation by condensing and liquefying vapor-phase refrigerant which was vaporized at the evaporation unit, and piping which connects the evaporation unit with the condensation unit; wherein the evaporation unit comprises an evaporation container and a partition wall section which is arranged within the evaporation container and constitutes a flow path of the refrigerant, and the height of the partition wall section is equal to or larger than the height of the vapor-liquid interface of the refrigerant and is smaller than the height of the evaporation container.

### TECHNICAL FIELD

The present invention relates to a cooling device for semiconductor devices and electronic devices, and in particular, relates to a cooling device based on a boiling cooling method which performs transport and radiation of heat by the use of phase transition cycles between vaporization and condensation of refrigerant, and also to an electronic device using the cooling device.

### BACKGROUND ART

In recent years, in association with advances in performance and functionality of semiconductor devices, electronic devices and the like, the amount of their heat generation has also been increasing. Accordingly, in case a cooling device using a heat pipe to achieve circulation of working fluid by the capillary force is used, there has been a problem in that dry-out of the working fluid occurs and accordingly the cooling performance is deteriorated. In contrast, in a cooling device using a boiling cooling method (thermo-siphon) which performs transport and radiation of heat by the use of phase transition cycles between vaporization and condensation of refrigerant and recirculation of the refrigerant by gravity, the thermal transport capability can be improved because the refrigerant moves as a vapor-liquid two-phase flow. Accordingly, it is expected as a cooling device for semiconductor devices, electronic devices and the like generating a large amount of heat.

Patent literature 1 describes an example of such a cooling device based on a boiling cooling method (hereafter, referred to also as a “boiling cooling device”). FIG. 12 is a cross-sectional side view showing a configuration of a related boiling cooling device 500 described in Patent Literature 1. The related boiling cooling device 500 is used for cooling a semiconductor device 502, such as a CPU, mounted on a circuit board 501, which is a heat generation source. The related boiling cooling device 500 comprises an evaporation unit (evaporator) 510 installed onto the top surface of the semiconductor device 502 and a condensation unit (condenser) 520 comprising a radiator, where a pair of pipes consisting of a vapor pipe 531 and a liquid return pipe 532 are installed between them. The related boiling cooling device 500 is configured as a thermo-siphon with its inside kept in a reduced (low) pressure state of approximately one-tenth of atomic pressure, which can circulate refrigerant fluid by the use of phase transition of water, which is a liquid refrigerant used as the refrigerant fluid, without any external power such as an electrical pump.

In the related boiling cooling device 500, heat generated at the semiconductor device 502 being a heat generation source is transmitted to the evaporation unit 510. As a result, in the evaporation unit 510, the water (Wa) being liquid refrigerant is boiled and evaporated by the transmitted heat under the reduced pressure, and thus produced vapor (ST) is guided from the evaporation unit 510 to the condensation unit 520 passing through the vapor pipe 531. Then, in the condensation unit 520, the refrigerant vapor is cooled by air (AIR) sent by a cooling fan 540 or the like and thereby changes into liquid (water), which subsequently flows back to the evaporation unit 510 through the liquid return pipe 532 by the effect of gravity.

Here, the condensation unit 520 is provided with a plurality of flat pipes, in whose inner wall surfaces a large number of fine grooves are formed. Patent Literature 1 describes that, by having such a configuration, it becomes possible to improve the condensation heat transfer rate and thereby improve the performance of the condensation unit 520, and accordingly cooling of heat generated by a heat generating body can be performed efficiently at low cost.

### CITATION LIST

### Patent Literature

PATENT LITERATURE 1 Japanese Patent Application Laid-Open No. 2011-047616 (paragraphs [0023] to [0049], FIG. 1)

### DISCLOSURE OF INVENTION

### Problem to be Solved by the Invention

In recent years, in association with widespread operation of a data center or the like which uses a great number of computers of various kinds such as a server, thinning of a rack for holding an electronic device such as a server is conducted. In terms of the size of such a rack, a standard is determined by the Electronic Industries Alliance (EIA), where the minimum unit “1 U (Unit)” of the rack height is defined to be 1.75 inches (44.45 mm).

In an electronic device such as a server, a socket or the like for maintenance and replacement of a central processing unit (CPU) is mounted on a circuit board. Accordingly, in a low-profile electronic device such as a server to be installed in a rack with “1 U” height (hereinafter, referred to also as a “1 U server”), the height of a space available for installing a cooling device used for cooling a CPU is limited to about 25 mm.

On the other hand, as described above, because the related boiling cooling device employs a thermo-siphon method using the buoyancy of refrigerant vapor and the gravity of liquid refrigerant, it needs to have a configuration of arranging the condensation unit above the evaporation unit in the vertical direction. However, if the condensation unit and the evaporation unit are arranged together in a space of about 25 mm height mentioned above, a sufficient height difference between them cannot be obtained, and accordingly the flowing back of the refrigerant by its gravity is retarded. As a result, it becomes difficult to achieve sufficient cooling performance.

Thus, the related boiling cooling device has a problem in that it cannot exhibit sufficient cooling performance when installed in a low-profile electronic device.

The objective of the present invention is to provide a cooling device and an electronic device using the same, which can solve the above-described problem in that a cooling device based on a boiling cooling method cannot exhibit sufficient cooling performance when installed in a low-profile electronic device.

### Means for Solving a Problem

A cooling device of the present invention includes an evaporation unit which stores refrigerant, a condensation unit which performs heat radiation by condensing and liquefying the refrigerant in vapor phase which was vaporized at the evaporation unit, and piping which connects the evaporation unit with the condensation unit; wherein the evaporation unit comprises an evaporation container and a partition wall section which is arranged within the evaporation container and constitutes a flow path of the refrigerant, and the height of the partition wall section is equal to or larger than that of the vapor-liquid interface of the refrigerant and is smaller than that of the evaporation container.

An electronic device of the present invention includes a cooling device, a heat generating body and a heat radiation unit, wherein: the cooling device includes an evaporation unit which stores refrigerant, a condensation unit which performs heat radiation by condensing and liquefying the refrigerant in vapor phase which was vaporized at the evaporation unit, and piping which connects the evaporation unit with the condensation unit, wherein the evaporation unit comprises an evaporation container and a partition wall section which is arranged within the evaporation container and constitutes a flow path of the refrigerant, and the height of the partition wall section is equal to or larger than that of the vapor-liquid interface of the refrigerant and is smaller than that of the evaporation container; the evaporation unit is arranged to be thermally connected onto the top of the heat generating body; and the condensation unit is arranged to be thermally connected onto the top of the heat radiation unit.

### Effect of the Invention

As an example of the effect of the cooling device by the present invention, it becomes possible to obtain a cooling device based on a boiling cooling method which exhibits sufficient cooling performance even when installed in a low-profile electronic device.

### BRIEF DESCRIPTION OF THE DRAWINGS

FIG. 1 is a cross-sectional side view showing a configuration of the cooling device according to the first exemplary embodiment of the present invention.

FIG. 2 is a cross-sectional side view showing a configuration of the cooling device according the second exemplary embodiment of the present invention.

FIG. 3 is a cross-sectional plan view showing the configuration of the cooling device according to the second exemplary embodiment of the present invention.

FIG. 4 is a cross-sectional view showing another configuration of a condensation unit in the cooling device according to the second exemplary embodiment of the present invention.

FIG. 5 is a cross-sectional plan view showing another configuration of the cooling device according to the second exemplary embodiment of the present invention.

FIG. 6A is a cross-sectional side view showing a configuration of the cooling device according to the third exemplary embodiment of the present invention.

FIG. 6B is a cross-sectional view taken on the line b-b of FIG. 6A showing the configuration of the cooling device according to the third exemplary embodiment of the present invention.

FIG. 7 is a perspective view showing a configuration of a heat radiation unit and a condensation plate section in the cooling device according to the third exemplary embodiment of the present invention.

FIG. 8A is a cross-sectional side view showing another configuration of the cooling device according to the third exemplary embodiment of the present invention.

FIG. 8B is a cross-sectional plan view showing the another configuration of the cooling device according to the third exemplary embodiment of the present invention.

FIG. 8C is a cross-sectional view taken on the line c-c of FIG. 8B showing the another configuration of the cooling device according to the third exemplary embodiment of the present invention.

FIG. 9 is a cross-sectional view showing another configuration of the heat radiation unit and the condensation unit in the cooling device according to the third exemplary embodiment of the present invention.

FIG. 10 is a cross-sectional view showing still another configuration of the heat radiation unit and the condensation unit in the cooling device according to the third exemplary embodiment of the present invention.

FIG. 11 is a cross-sectional side view showing a configuration of the electronic device according to the fourth exemplary embodiment of the present invention.

FIG. 12 is a cross-sectional side view showing a configuration of a related boiling cooling device.

FIG. 13 is a cross-sectional top view showing another configuration of an evaporation unit in the cooling device according to the first exemplary embodiment of the present invention.

FIG. 14 is a cross-sectional top view showing still another configuration of the evaporation unit in the cooling device according to the first exemplary embodiment of the present invention.

FIG. 15 is a cross-sectional side view showing yet another configuration of the evaporation unit in the cooling device according to the first exemplary embodiment of the present invention.

FIG. 16 is a cross-sectional side view showing further another configuration of the evaporation unit in the cooling device according to the first exemplary embodiment of the present invention.

FIG. 17 is a cross-sectional side view showing further another configuration of the evaporation unit in the cooling device according to the first exemplary embodiment of the present invention.

FIG. 18 is a cross-sectional side view showing further another configuration of the evaporation unit in the cooling device according to the first exemplary embodiment of the present invention.

FIG. 19 is a cross-sectional top view showing further another configuration of the evaporation unit in the cooling device according to the first exemplary embodiment of the present invention.

FIG. 20 is a cross-sectional side view showing the another configuration shown in FIG. 19 of the evaporation unit in the cooling device according to the first exemplary embodiment of the present invention.

FIG. 21 is a cross-sectional top view showing further another configuration of the evaporation unit in the cooling device according to the first exemplary embodiment of the present invention.

FIG. 22 is a cross-sectional side view showing the another configuration shown in FIG. 21 of the evaporation unit in the cooling device according to the first exemplary embodiment of the present invention.

FIG. 23 is a cross-sectional top view showing further another configuration of the evaporation unit in the cooling device according to the first exemplary embodiment of the present invention.

FIG. 24 is a cross-sectional side view showing the another configuration shown in FIG. 23 of the evaporation unit in the cooling device according to the first exemplary embodiment of the present invention.

FIG. 25 is a cross-sectional top view showing further another configuration of the evaporation unit in the cooling device according to the first exemplary embodiment of the present invention.

FIG. 26 is a cross-sectional side view showing the another configuration shown in FIG. 25 of the evaporation unit in the cooling device according to the first exemplary embodiment of the present invention.

FIG. 27 is a cross-sectional top view showing further another configuration of the evaporation unit in the cooling device according to the first exemplary embodiment of the present invention.

FIG. 28 is a cross-sectional side view showing the another configuration shown in FIG. 27 of the evaporation unit in the cooling device according to the first exemplary embodiment of the present invention.

FIG. 29 is a cross-sectional side view showing another configuration of the cooling device according to the first exemplary embodiment of the present invention.

FIG. 30 is a cross-sectional side view showing further another configuration of the evaporation unit in the cooling device according to the first exemplary embodiment of the present invention.

FIG. 31 is a cross-sectional side view showing further another configuration of the evaporation unit in the cooling device according to the first exemplary embodiment of the present invention.

FIG. 32 is a cross-sectional side view showing further another configuration of the evaporation unit in the cooling device according to the first exemplary embodiment of the present invention.

FIG. 33A is a cross-sectional side view showing still another configuration of the cooling device according to the first exemplary embodiment of the present invention, where the cooling device is in operation.

FIG. 33B is a cross-sectional side view showing the still another configuration shown in FIG. 33A of the cooling device according to the first exemplary embodiment of the present invention, where the cooling device is in the initial state and not in operation.

FIG. 34A is a cross-sectional side view showing yet another configuration of the cooling device according to the first exemplary embodiment of the present invention, where the cooling device is in operation.

FIG. 34B is a cross-sectional side view showing the yet another configuration shown in FIG. 34A of the cooling device according to the first exemplary embodiment of the present invention, where the cooling device is in the initial state and not in operation.

FIG. 35 is a cross-sectional top view showing further another configuration of the cooling device according to the first exemplary embodiment of the present invention

### DESCRIPTION OF EMBODIMENTS

Exemplary embodiments of the present invention will be described below, with reference to drawings.

### First Exemplary Embodiment

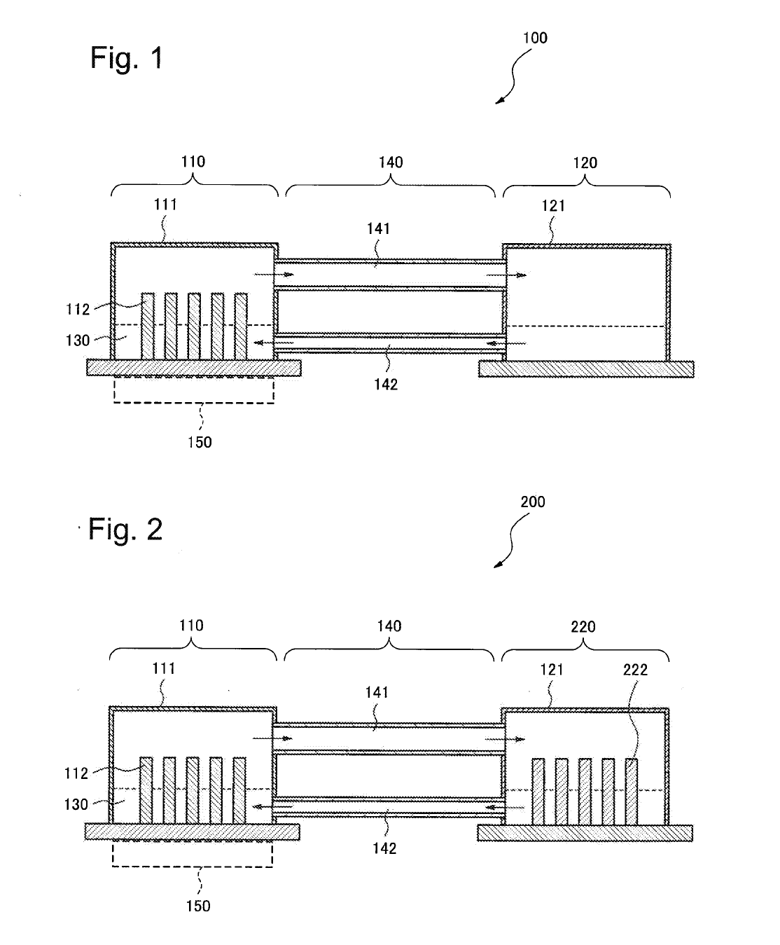

FIG. 1 is a cross-sectional side view showing a configuration of a cooling device 100 according to the first exemplary embodiment of the present invention. The cooling device 100 includes an evaporation unit 110 which stores refrigerant 130, a condensation unit 120 which performs heat radiation by condensing and liquefying the refrigerant in vapor phase (vapor-phase refrigerant) which was vaporized at the evaporation unit 110, and piping 140 which connects the evaporation unit 110 with the condensation unit 120. Here, the evaporation unit 110 and the condensation unit 120 are located at approximately the same height in the vertical direction. The evaporation unit 110 includes an evaporation container 111 and a partition wall section 112 which is arranged within the evaporation container 111 and partitions the refrigerant 130, where the height of the partition wall section 112 is equal to or larger than that of the vapor-liquid interface of the refrigerant 130 and is smaller than that of the evaporation container 111.

If described in more detail, the partition wall section 112 restricts a flow direction of the refrigerant 130 and constitutes its flow path. Here, the partition wall section 112 is configured such that the refrigerant 130 circulates within the evaporation container 111. In the evaporation unit 110 of FIG. 1, there are spaces between the partition wall section 112 and the side walls of the evaporation container 111, so that the refrigerant flows there. Alternatively, it may be configured to form a flow path such as by providing a hole in the partition wall section 112 so that the refrigerant circulates there.

The height of the evaporation container 111 means the inner height of the evaporation container 111, that is, the height of its inner wall up to its ceiling surface.

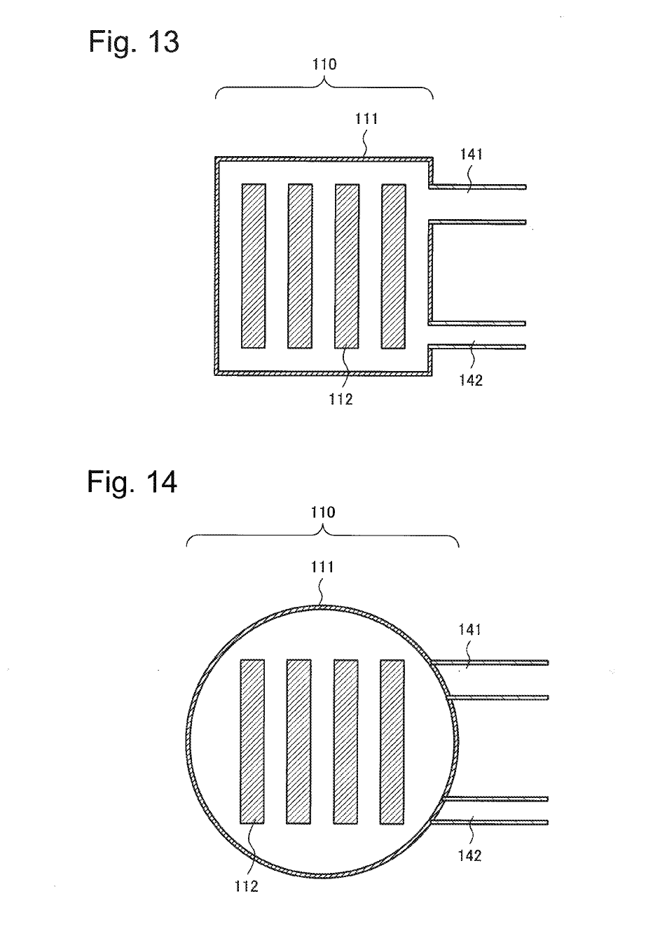

Further, the shape of the evaporation container 111 may be cubic as shown in a cross-sectional top view of the evaporation unit 110 of FIG. 13, and may also be cylindrical as shown in a cross-sectional top view of the evaporation unit 110 of FIG. 14.

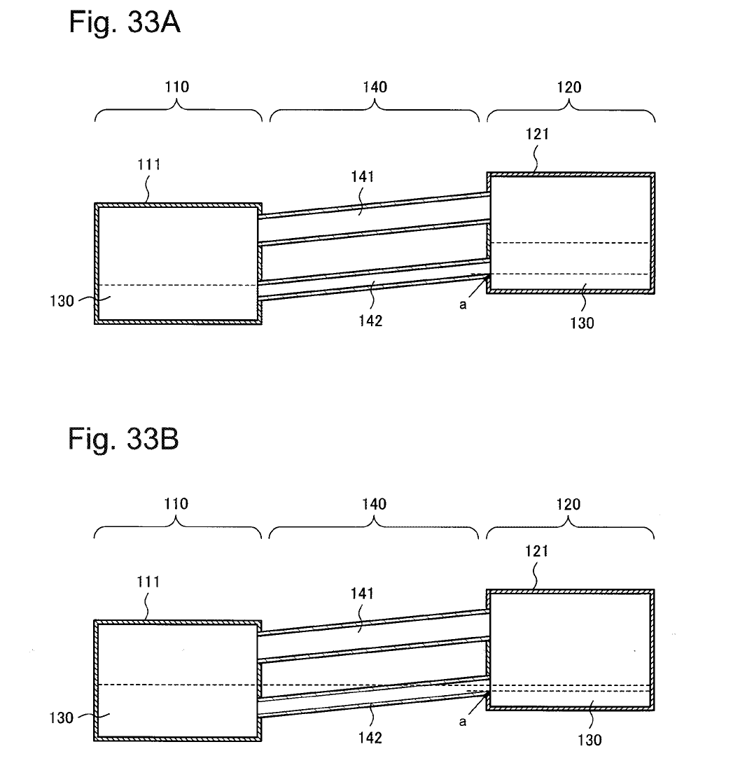

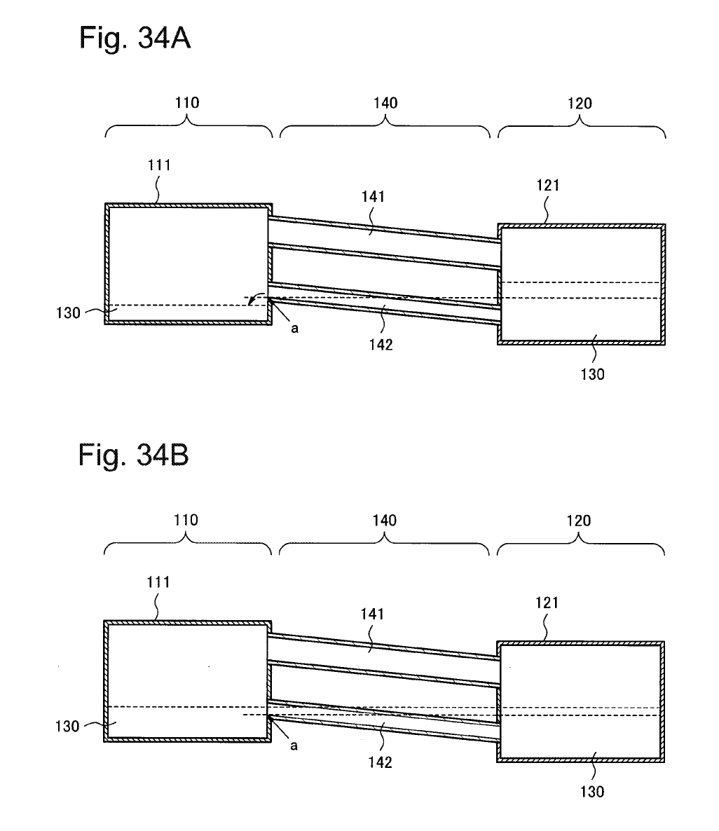

Although it has been determined above that, in the present exemplary embodiment, the evaporation unit 110 and the condensation unit 120 are located at approximately the same height in the vertical direction, it is not the only way of enabling the present invention to operate. For enabling the present invention to operate, it is only necessary that, in its state of operating as a cooling device, the liquid level in the condensation container 121 is higher than the bottom surface part a of one of two liquid pipe mouths which is connected at a higher position than the other one of the mouths. In order to maintain that state, it is only necessary that, in the initial state where the present invention is not in operation, the liquid level in the evaporation container 111 and that in the condensation container 121 are both equal to or higher than the height of the bottom surface part a of one of two liquid pipe mouths which is connected at a higher position than the other one of the mouths. As long as this condition is satisfied, the condensation unit 120 may be located at a higher position than the evaporation unit 110, as shown in cross-sectional side views of FIGS. 33A and 33B, and the condensation unit 120 may also be located at a lower position than the evaporation unit 110, as shown in FIGS. 34A and 34B. Here, in FIGS. 33A and 34A, the liquid levels of the refrigerant are illustrated as that in a state of operating as a cooling device, and in FIG. 33B and FIG. 34B, they are illustrated as that in the initial state of not operating as a cooling device. In the state of being not in operation, the liquid level of the refrigerant is at the same height in both the evaporation container 111 and the condensation container 121.

By using a low boiling point material for the refrigerant 130 and evacuating the evaporation container 111 after injecting the refrigerant 130 into it, the inside of the evaporation container 111 can be kept at the saturation vapor pressure of the refrigerant 130. In the drawings, hatched portions within the evaporation unit 110 and the condensation unit 120 represent the refrigerant in the liquid phase state, and dotted lines within the hatched portions each represent an interface between the refrigerant in the liquid phase state and that in the vapor phase state (hereafter, referred to as a “vapor-liquid interface of refrigerant”). As the refrigerant 130, for example, low boiling point refrigerants such as hydro-fluorocarbon and hydro-fluoroether, which are insulating and inactive materials, may be used. For a material forming the evaporation unit 110 and the condensation unit 120, metals having excellent thermal conductivity such as aluminum and copper, for example, may be used.

Next, operation of the cooling device 100 according to the present exemplary embodiment will be described in detail. The cooling device 100 is used in a configuration where the heat generating body 150 such as a central processing unit (CPU) or the like is arranged at the bottom of the evaporation unit 110 in a manner to thermally connect them with each other. Heat generated by the heat generating body is transmitted to the refrigerant 130 via the evaporation container 111 of the evaporation unit 110, and accordingly the refrigerant 130 is vaporized. At that time, since the heat generated by the heat generating body is taken by the refrigerant as the vaporization heat, temperature rise of the heat generating body is suppressed.

Here, the amount of the refrigerant 130 to be injected is determined such that it becomes equal to or larger than a value calculated from the amount of heat generated by the heat generating body 150 and the vaporization heat of the refrigerant, and also such that the height of the vapor-liquid interface of the refrigerant 130 becomes equal to or larger than the height of the partition wall section 112. The height of the partition wall section 112 is desired to be one producing a space of about 5 to 10 mm arranged between the top end of the partition wall section 112 and the top plate of the evaporation container 111.

Refrigerant vapor generated by vaporization at the evaporation unit 110 expands its volume from that in the liquid phase and fills the evaporation container 111, where pressure variation within the evaporation container 111 is created because of the existence of the partition wall section 112. Specifically, since the height of the partition wall section 112 is equal to or larger than that of the vapor-liquid interface of the refrigerant 130, refrigerant vapor also exists in the area of the partition wall section 112. However, in the area of the partition wall section 112, because the refrigerant vapor is partitioned by the partition wall section 112, its volume expansion is restricted. As a result, the pressure of the refrigerant vapor becomes higher in the area of the partition wall section 112 than in the area between the top end of the partition wall section 112 and the top plate of the evaporation container 111. Here, the partition wall section 112 may have a configuration, for example, including a plurality of partition wall thin plates (fins) each of which includes a rectangle-shaped thin plate standing upright. In that case, the volume occupied by the refrigerant vapor in the area of the partition wall section 112 is restricted by the spaces between the partition wall thin plates (fins).

Here, a description will be given of the shape of the partition wall thin plates (fins) constituting the partition wall section 112. The higher the height of the fins is, the larger the total area of the fins becomes, and accordingly the cooling performance can be improved. If installation into a 1 U server is considered, since the inner height of the 1 U server is about 40 mm and the height of a CPU is about 15 mm, the outer and inner heights of the evaporation unit 110 are calculated to be about 25 mm and about 20 mm, respectively, and accordingly the height of the fins is preferred to be about 10 to 15 mm. The smaller the interval between the fins (fin pitch) is, the larger the number of fins becomes, and accordingly the cooling performance can be improved. On the other hand, when the fin pitch is too small, a flow of the vapor becomes difficult, and accordingly the cooling performance is deteriorated, and therefore, the fin pitch is preferred to be about 1 to 2 mm. The thickness of the fins is preferred to be about a half of the fin pitch, that is, about 0.5 to 1 mm. If the thickness of the fins is too small, the heat cannot be conducted sufficiently up to the top end of the fins, and if it is too large, a flow of bubbles becomes difficult; accordingly, the cooling performance is deteriorated in the both cases. For this reason, the cooling performance can be improved by setting the thickness of the fins to be a half of the fin pitch so as to make the vapor pressure between the fins be twice that in the other areas.

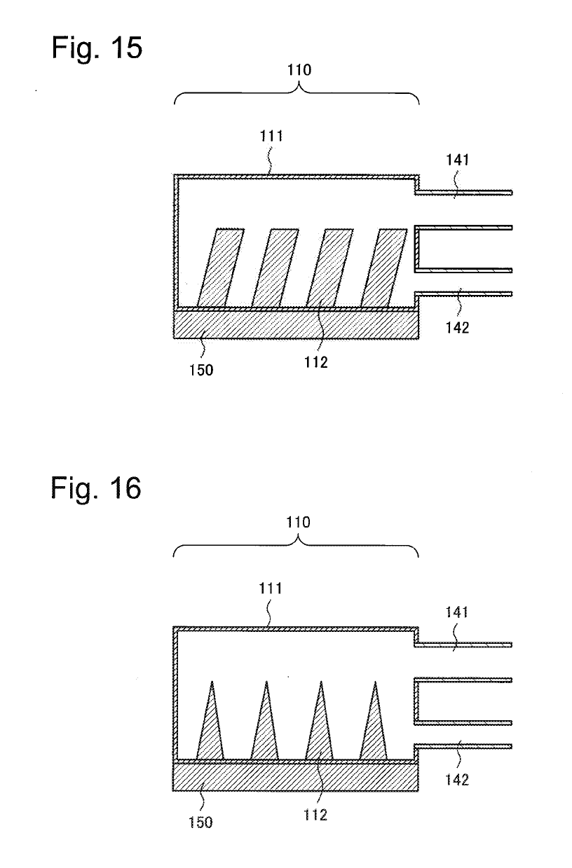

Further, the fins may be ones standing upright in the direction of gravity, as shown in the cross-sectional side view of the cooling device 100 in FIG. 1, and may also be ones standing upright with a tilt toward the side of the pipes 141 and 142, as shown in the cross-sectional side view of the evaporation unit 110 in FIG. 15.

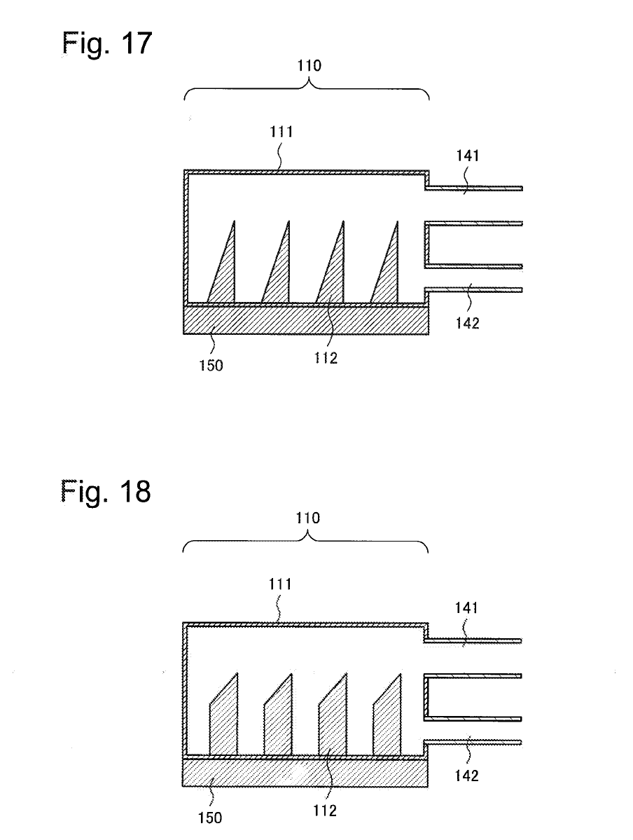

Still further, the shape of the fins is not limited to a rectangle-shaped thin plate shown in the cross-sectional side view of the cooling device 100 in FIG. 1, and may also be a thin plate with a triangle-shaped cross section as shown in cross-sectional side views of the evaporation unit 110 in FIGS. 16 and 17. In FIG. 16, both sides of each of the fins are tilted, and in FIG. 17, only one of the sides is tilted. When the fins are each given a tilted surface(s) in such ways, upward movement of the vapor becomes easy, the flow path resistance is accordingly reduced, the boiling point is accordingly lowered, and as a result, the cooling performance is improved. Further, the shape of the fins may also be a thin plate with its top end tapered, as shown in a cross-sectional side view of the evaporation unit 110 in FIG. 18. In that case, because the fins can be produced by a press forming method, the cost can be reduced.

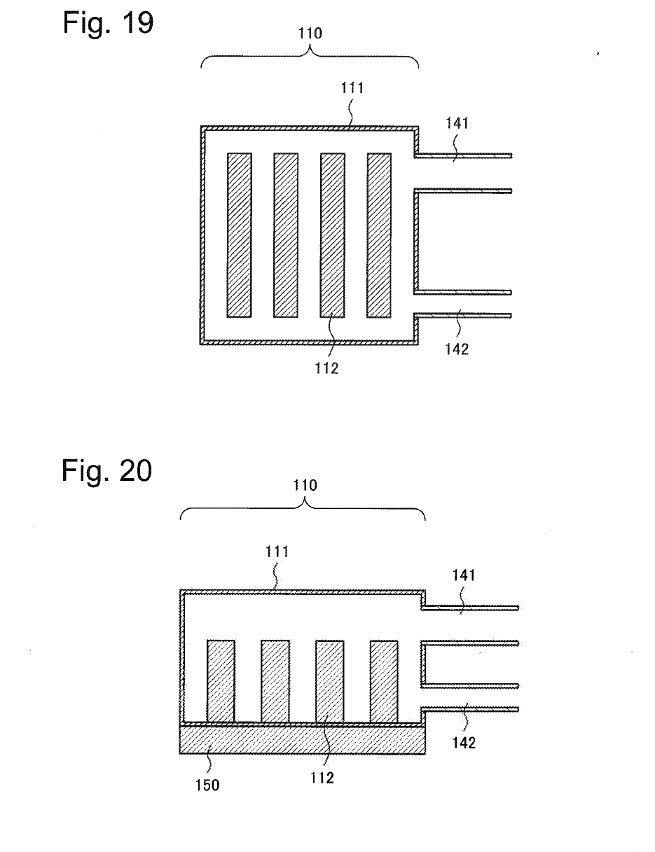

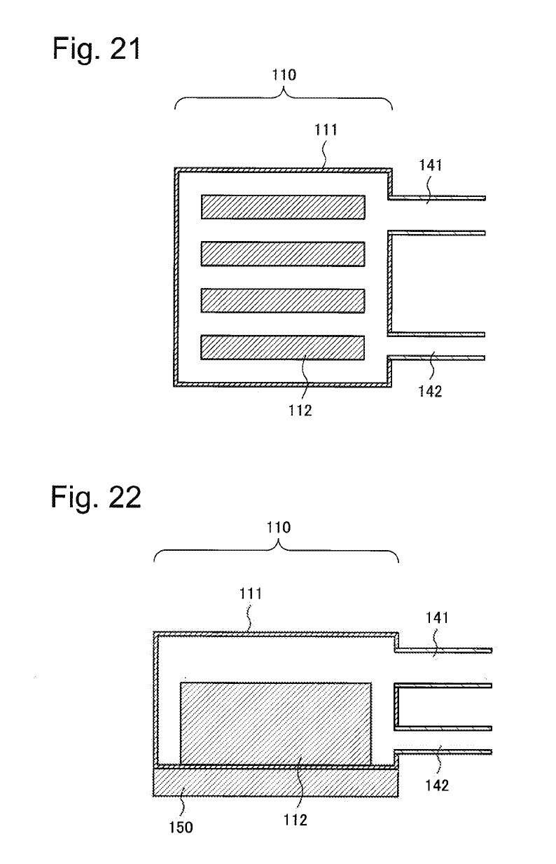

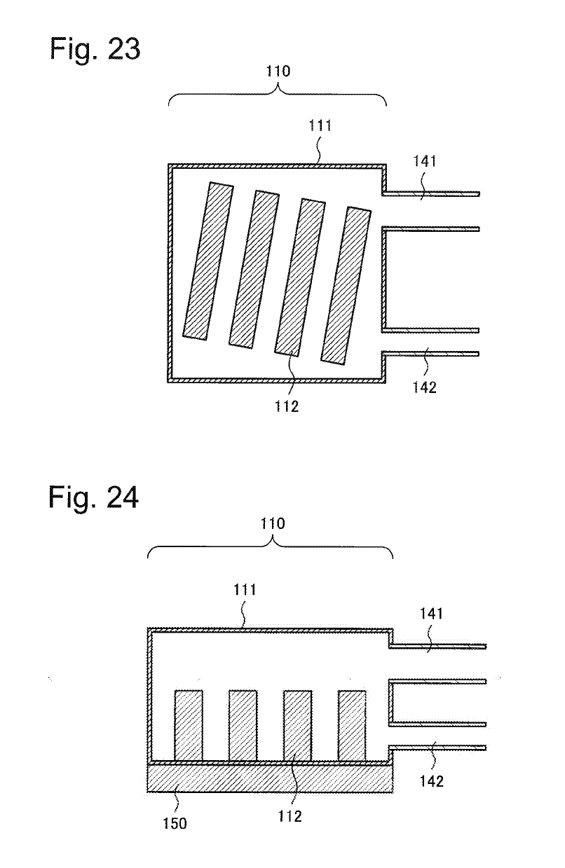

Next, a description will be given of arrangement of the partition wall section 112. When viewed in a cross-sectional top view, the elongated direction (longitudinal direction) of the fins included in the partition wall section 112 may be arranged such that it crosses perpendicularly with the elongated direction of the piping 140, as shown in a top view of the evaporation unit 110 in FIG. 19 and in a cross-sectional view of that in FIG. 20, and may also be arranged such that it runs in the same direction as the elongated direction of the piping 140, as shown in a top view of the evaporation unit 110 in FIG. 21 and in a cross-sectional view of that in FIG. 22. Further, it may also be arranged to be diagonal to the elongated direction of the piping 140, as shown in a top view of the evaporation unit 110 in FIG. 23 and in a cross-sectional view of that in FIG. 24. In that case, the longitudinal direction of the fins does not necessarily need to be parallel to a side wall of the evaporation container 111.

On the other hand, in the condensation unit 120, refrigerant vapor is cooled by its contacting the condensation container 121 or the like, and is thereby condensed and liquefied. Because the volume of the refrigerant vapor reduces rapidly at a time of its phase transition into the liquid, the pressure originating from vapor-phase refrigerant becomes lower in the condensation container 121 than in the evaporation container 111. As a result, a pressure gradient is generated among the partition wall section 112 in the evaporation unit 110, the area between the top end of the partition wall section 112 and the top plate of the evaporation container 111, also in the evaporation unit 110, and the condensation container 121, where the pressure decreases in this order. Accordingly, according to the cooling device 100 of the present exemplary embodiment, even when the evaporation unit 110 and the condensation unit 120 are located at approximately the same height in the vertical direction and accordingly circulation of refrigerant vapor by its buoyancy cannot be used, it becomes possible to transport the refrigerant vapor from the evaporation unit 110 to the condensation unit 120.

In the evaporation unit 110, by the refrigerant in the liquid phase being vaporized to desorb in the form of bubbles, the vapor-liquid interface of the refrigerant in the evaporation unit 110 is lowered. However, liquid-phase refrigerant is immediately supplied from the condensation unit 120 to the evaporation unit 110 through the piping 140 so as to keep the vapor-liquid interface of the refrigerant at the same level in both the evaporation unit 110 and the condensation unit 120. As a result, even when the evaporation unit 110 and the condensation unit 120 are located at approximately the same height in the vertical direction and accordingly circulation of liquid phase refrigerant by gravity cannot be used, it becomes possible to circulate the liquid-phase refrigerant between the evaporation unit 110 and the condensation unit 120.

Here, the piping 140 may be configured to comprise a vapor pipe 141 in which the vapor-phase refrigerant flows and a liquid pipe 142 in which the liquid-phase refrigerant generated by condensation and liquefaction flows. In that case, it is desirable to configure them such that the vapor pipe 141 is connected to the evaporation container 111 at a position of a height equal to or higher than the height of the partition wall section 112 and the liquid pipe 142 is connected to the evaporation container 111 at a position of a height equal to or lower than the height of the vapor-liquid interface of the refrigerant.

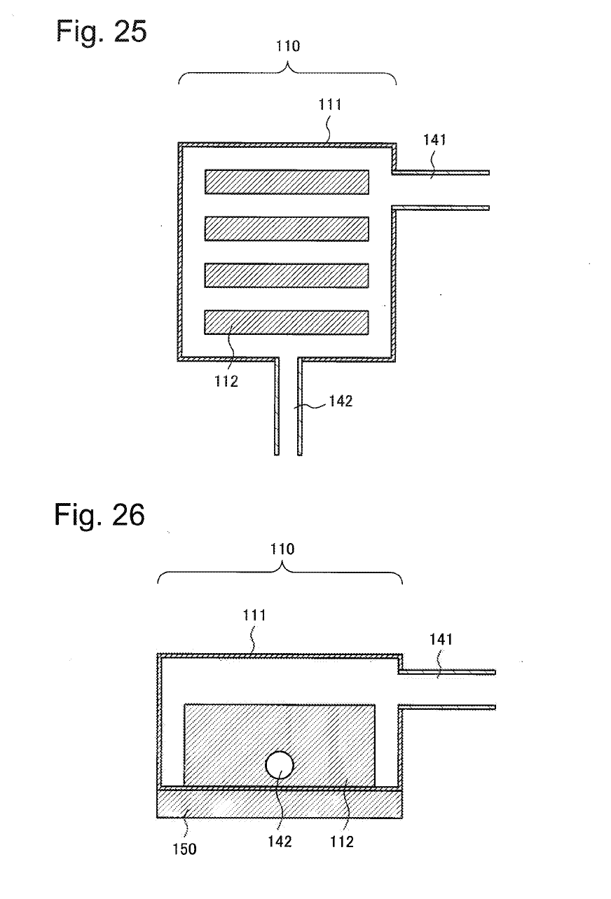

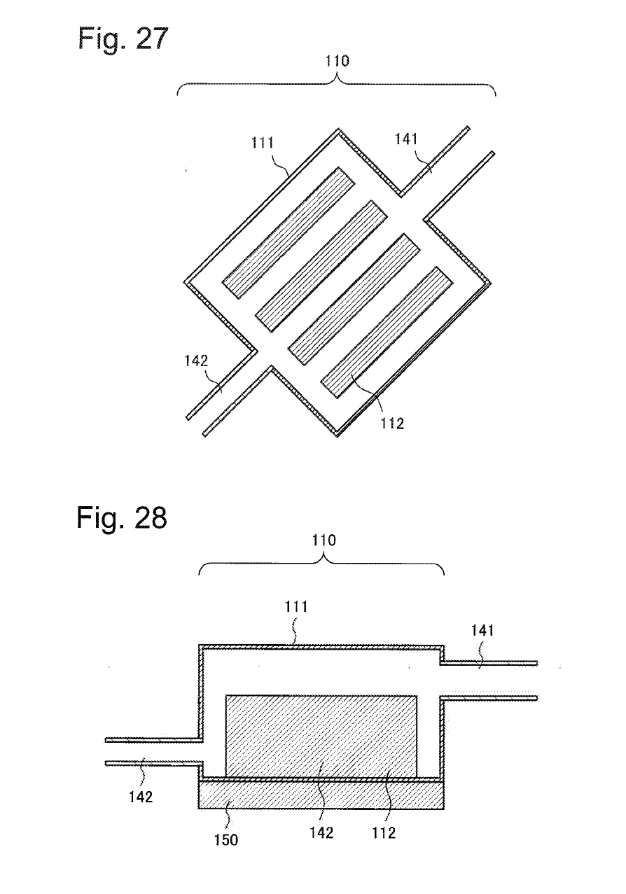

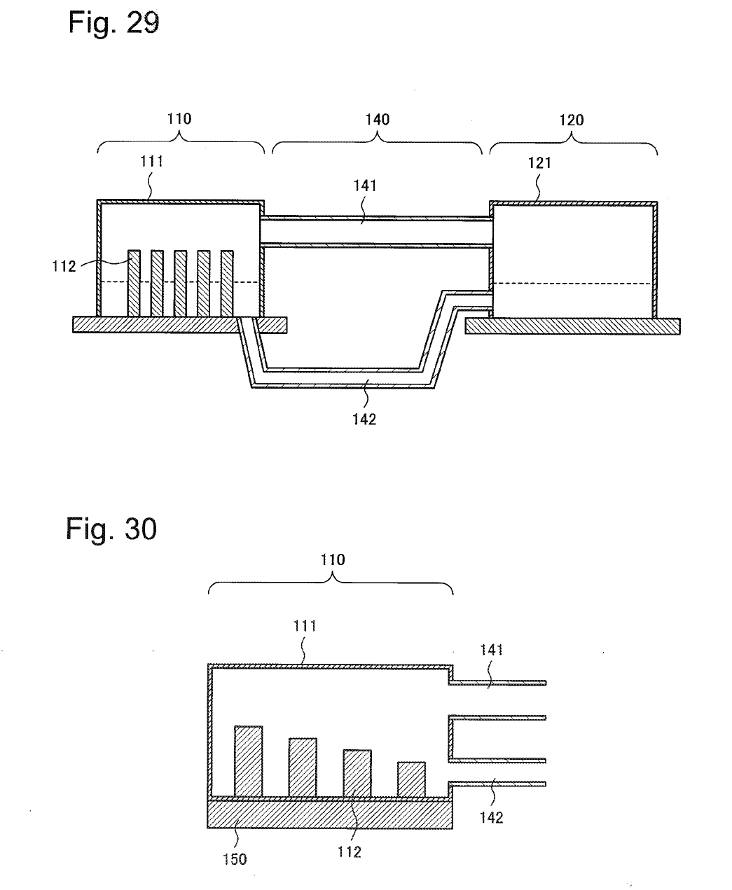

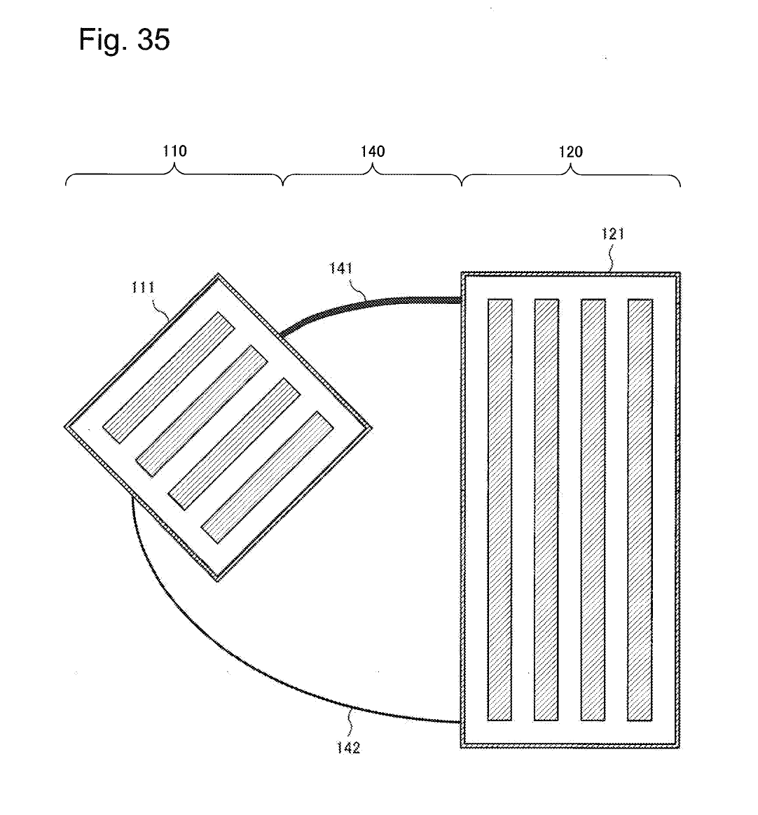

As long as the vapor pipe 141 is located at a higher position than that of the liquid pipe 142 in the direction of gravity, the vapor pipe 141 and the liquid pipe 142 may be arranged in any way regardless of their positional relationship with the longitudinal direction of the fins, and accordingly, for example, they may be connected to different side walls of the evaporation container 111, as shown in a top view of the evaporation unit 110 in FIG. 25 and a cross-sectional side view of that in FIG. 26. In order to reduce resistance to a vapor flow, the vapor pipe 141 and the liquid pipe 142 may be connected to respective ones of two side walls of the evaporation container 111 facing each other, as shown in a top view of the condensation unit 110 in FIG. 27 and a cross-sectional side view of that in FIG. 28. It is preferable in particular that the longitudinal direction of the fins is arranged to be the same as that of the liquid pipe and vapor pipe. This is because resistance to a vapor flow induces pressure loss and thus raises the boiling point, and accordingly the resistance is desired to be as low as possible in order to increase the cooling performance. In that case, as shown in FIG. 35, by connecting the liquid pipe and the vapor pipe to the evaporation unit 110 and to the condensation unit 120 in a manner to bend the pipes in curved forms and also arranging the evaporation unit 110 diagonally to the condensation unit 120, the liquid pipe can be reduced in length and its connection to the condensation unit 120 can be made easy. Further, as shown in a cross-sectional side view of the cooling device in FIG. 29, the liquid pipe 142 may be connected to the bottom surface of the evaporation container 111. By employing such a configuration, the amount of refrigerant can be reduced, and more flexible piping design also becomes possible.

The diameter of the vapor pipe 141 is determined by the amount of evaporation of the refrigerant, that is, the amount of heat generated by the heat generating body, and may be set at any value enabling a sufficient amount of vapor to pass through it.

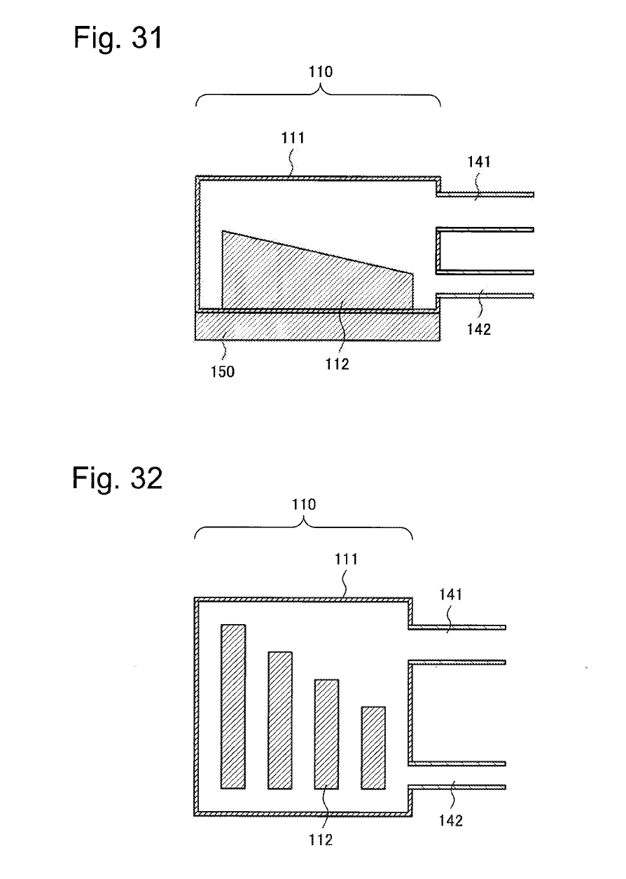

Further, a description will be given of a relationship between the vapor pipe 141 and the fins constituting the partition wall section 112. Because the amount of vapor increases with getting closer to the vapor pipe 141 in the evaporation container 111, in order to enable the vapor to pass through easily, the fins may be configured to become smaller in height with getting closer to the vapor pipe 141, as shown in cross-sectional side views of the evaporation unit 110 in FIGS. 30 and 31. Alternatively, the fins may be configured to become smaller in length with getting closer to the vapor pipe 141, as shown in a cross-sectional top view of the evaporation unit 110 in FIG. 32.

As has been described above, according to the cooling device 100 of the present exemplary embodiment, even when the evaporation unit 110 and the condensation unit 120 need to be arranged at approximately the same height in the vertical direction, such as when they are installed in a low-profile electronic device, it is possible to achieve a cooling device based on a boiling cooling method having sufficient cooling performance.

### Second Exemplary Embodiment

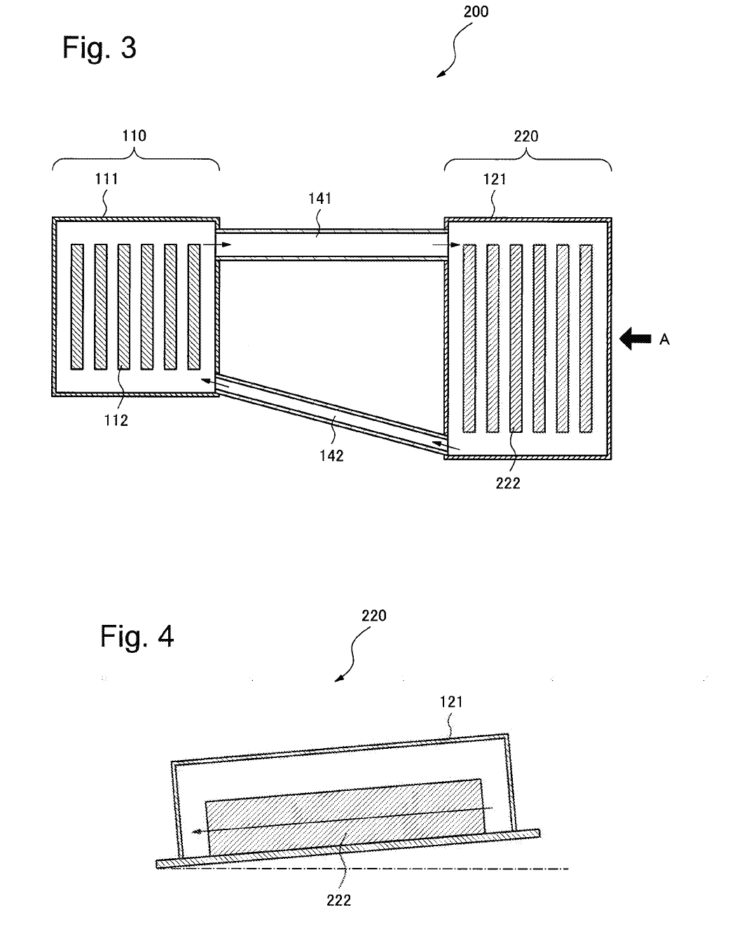

Next, a second exemplary embodiment of the present invention will be described. FIG. 2 is a cross-sectional side view showing a configuration of a cooling device 200 according to the second exemplary embodiment of the present invention, and FIG. 3 is its cross-sectional plan view. The cooling device 200 comprises the evaporation unit 110 which stores the refrigerant 130, a condensation unit 220 which performs heat radiation by condensing and liquefying vapor-phase refrigerant which was vaporized at the evaporation unit 110, and the piping 140 which connects the evaporation unit 110 with the condensation unit 220. Here, the evaporation unit 110 and the condensation unit 220 are located at approximately the same height in the vertical direction. The evaporation unit 110 comprises the evaporation container 111 and the partition wall section 112 which is arranged within the evaporation container 111 and partitions the refrigerant 130, where the height of the partition wall section 112 is equal to or larger than that of the vapor-liquid interface of the refrigerant 130 and is smaller than that of the evaporation container 111.

The cooling device 200 according to the present exemplary embodiment is different from the cooling device 100 of the first exemplary embodiment only in the configuration of the condensation unit 220, and accordingly, since the other configurations are the same as that of the cooling device 100, their detailed descriptions will be omitted. The condensation unit 220 comprises, within the condensation container 121, a condensation plate section 222 which accelerates heat radiation of the vapor-phase refrigerant. Because cooling and resulting condensation and liquefaction of refrigerant vapor are accelerated by the condensation plate section 222 in the condensation unit 220, the cooling performance of the cooling device 200 can be improved.

Here, the piping 140 may be configured to include the vapor pipe 141 in which vapor-phase refrigerant flows and the liquid pipe 142 in which liquid-phase refrigerant generated by condensation and liquefaction flows. In that case, it is desirable to configure them such that the vapor pipe 141 is connected to the condensation container 121 at a position of a height equal to or higher than the height of the condensation plate section 222 and the liquid pipe 142 is connected to the condensation container 121 at a position of a height equal to or lower than the height of the vapor-liquid interface of the refrigerant.

In order to condense and liquefy, at the condensation plate section 222, refrigerant vapor generated in the evaporation unit 110, the surface area of the condensation plate section 222 is desired to be as large as possible. Accordingly, the condensation plate section 222 may be configured to comprise a plurality of condensation thin plates (fins) consisting of rectangular thin plates standing upright. In that case, as shown in FIG. 3, the piping 140 is connected to the condensation container 121 at two portions of the latter near respective ones of the end regions of the condensation thin plates in their longitudinal direction. It is desirable to have a configuration, for example, in which the vapor pipe 141 is connected to the condensation container 121 at a portion of the latter near one of the end regions of the condensation thin plates in their longitudinal direction and the liquid pipe 142 is connected to the condensation container 121 at a portion of the latter near the other one of the end regions. In this configuration, refrigerant vapor having flowed from the vapor pipe 141 into the condensation container 121 flows toward the liquid pipe 142 along the longitudinal direction of the condensation thin plates. Accordingly, the rate of refrigerant vapor's contacting with the condensation thin plates (fins) increases, and through resulting improvement in the efficiency of condensation and liquefaction, the cooling performance can be improved.

In the condensation unit 220, as shown in FIG. 4, the condensation plate section 222 may be arranged such that the longitudinal direction of the condensation thin plates is tilted from a direction perpendicular to the vertical direction (the dashed-dotted line in FIG. 4). FIG. 4 is a cross-sectional view viewed from the direction of the arrow A in FIG. 3. In this configuration, because it becomes possible for liquid-phase refrigerant generated by condensation and liquefaction in the condensation container 121 to immediately move to the liquid pipe 142 by the effect of gravity, further improvement in the cooling performance can be achieved.

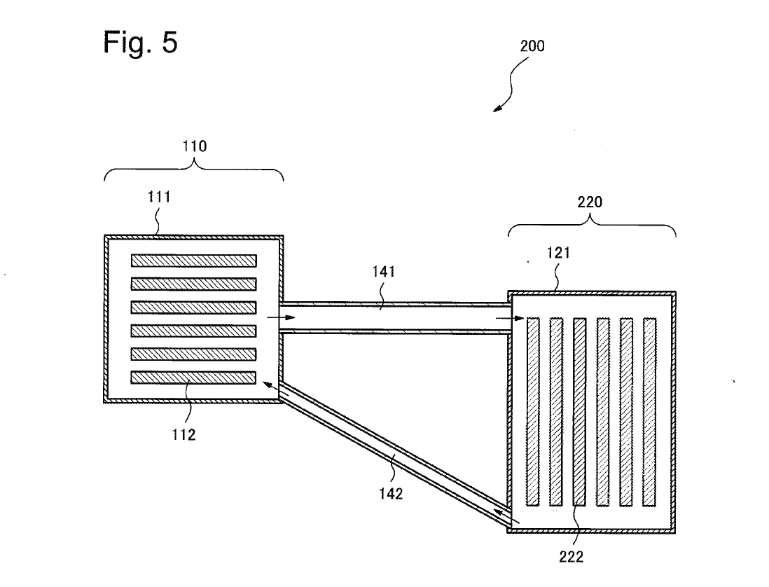

In FIG. 3, shown is a case where, also at the evaporation unit 110, the piping 140 is connected to the evaporation container 111 at two portions of the latter near respective ones of the end regions of the partition wall thin plates, in the partition wall section 112, in their longitudinal direction. That is, the configuration shown there is such that the vapor pipe 141 is connected to the evaporation container 111 at a portion of the latter near one of the end regions of the partition wall thin plates in their longitudinal direction and the liquid pipe 142 is connected to the evaporation container 111 at a portion of the latter near the other one of the end regions. In this configuration, the convection effect of refrigerant vapor is added, and accordingly improvement in the performance of the evaporation unit 110 can be achieved. An arrangement configuration of the piping 140 is not limited to the above-described one, and it may also be such that, as shown in FIG. 5, both the vapor pipe 141 and the liquid pipe 142 are connected to the evaporation container 111 at a portion of the latter near one end region of the partition wall thin plates in their longitudinal direction.

As has been described above, according to the cooling device 200 of the present exemplary embodiment, cooling and resulting condensation and liquefaction of refrigerant vapor are accelerated by the condensation plate section 222 arranged within the condensation container 121, and accordingly improvement in the cooling performance can be achieved.

### Third Exemplary Embodiment

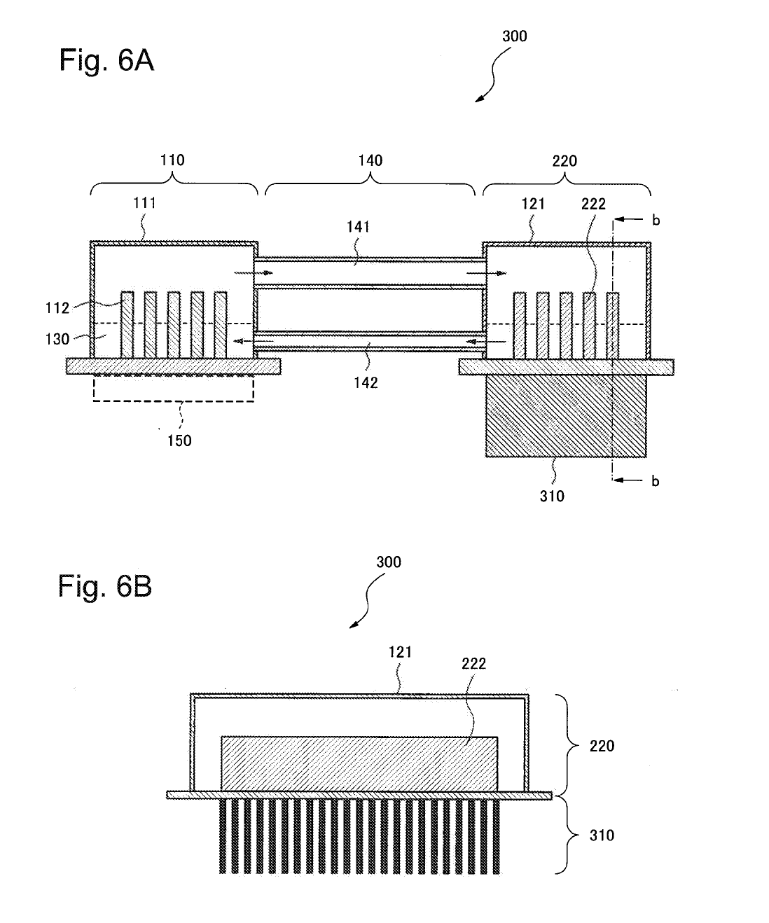

Next, a third exemplary embodiment of the present invention will be described. FIGS. 6A and 6B are diagrams showing a configuration of a cooling device 300 according to the third exemplary embodiment of the present invention, where FIG. 6A is its cross-sectional side view and FIG. 6B is its cross-sectional view taken on the line b-b in FIG. 6A. The cooling device 300 includes the evaporation unit 110 which stores the refrigerant 130, the condensation unit 220 which performs heat radiation by condensing and liquefying vapor-phase refrigerant which was vaporized at the evaporation unit 110, and the piping 140 which connects the evaporation unit 110 with the condensation unit 220. Here, the evaporation unit 110 and the condensation unit 220 are located at approximately the same height in the vertical direction. The evaporation unit 110 includes the evaporation container 111 and the partition wall section 112 which is arranged within the evaporation container 111 and partitions the refrigerant 130, where the height of the partition wall section 112 is equal to or larger than that of the vapor-liquid interface of the refrigerant 130 and is smaller than that of the evaporation container 111. The condensation unit 220 is configured to comprise, within the condensation container 121, the condensation plate section 222 which accelerates heat radiation of vapor-phase refrigerant.

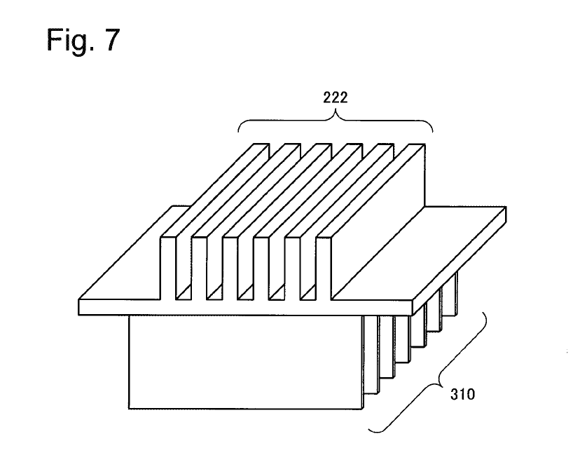

The cooling device 300 according to the present exemplary embodiment further comprises a heat radiation unit 310 which is thermally connected with the condensation unit 220. Because the other configurations are the same as that of the second exemplary embodiment, their detailed descriptions will be omitted. The heat radiation unit 310 may be formed using a metal having an excellent thermal conductive property, for example, aluminum, copper and the like, and may be formed in a fin-like structure consisting of a plurality of thin plates as shown in FIG. 6B. An example of a configuration of the heat radiation unit 310 and the condensation plate section 222 is shown in FIG. 7. The heat radiation unit 310 and the condensation plate section 222 may be formed as an integrated body, or may also be formed separately and then thermally connected with each other.

Because cooling and resulting condensation and liquefaction of refrigerant vapor in the condensation unit 220 are accelerated by the heat radiation unit 310, improvement in the cooling performance of the cooling device 300 can be achieved. Further, according to the cooling device 300 of the present exemplary embodiment, even in a configuration where the evaporation unit 110 and the condensation unit 220 are located at approximately the same height in the vertical direction, circulation of the refrigerant is possible. Accordingly, the heat radiation unit 310 may be arranged beneath the condensation unit 220, which is the same side as that of the heat generating body 150. Accordingly, it becomes unnecessary to secure another space for installing the heat radiation unit 310, and as a result, installation of the cooling device 300 in a low-profile electronic device becomes possible.

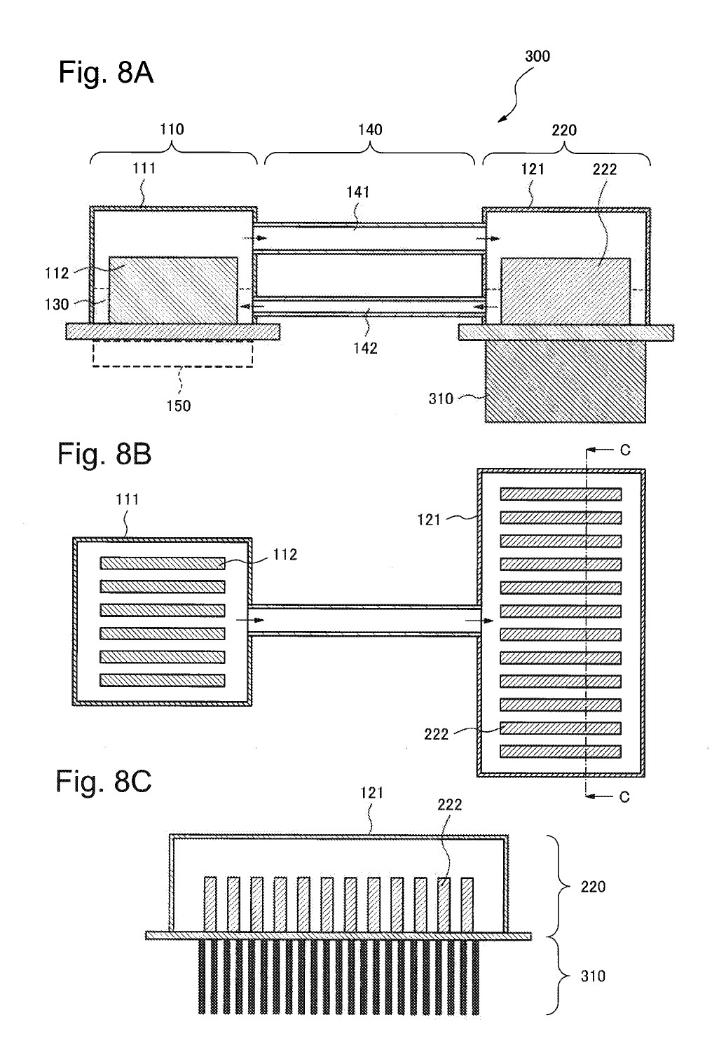

A configuration of the heat radiation unit 310 is not limited to the one shown in FIGS. 6A and 6B, and may be such that, as shown in FIGS. 8A, 8B and 8C, the direction of the thin plates (fins) constituting the heat radiation unit 310 is the same as that of the condensation thin plates constituting the condensation plate section 222. Here, FIG. 8A is a cross-sectional side view, FIG. 8B a cross-sectional plan view, and FIG. 8C a cross-sectional view taken on the line c-c in FIG. 8B.

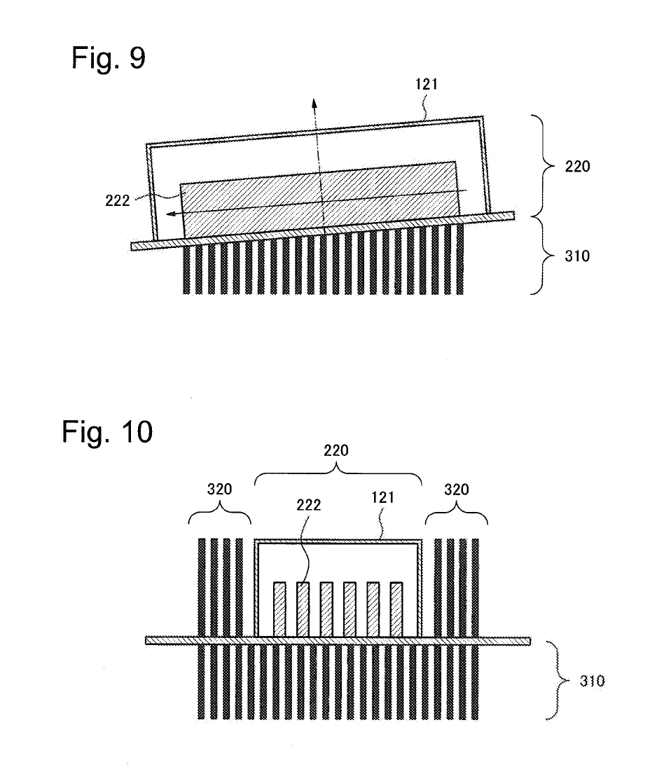

The heat radiation unit 310 may also be configured such that, as shown in FIG. 9, it has one principal surface thermally connected to the condensation unit 220 and the normal of the principal surface (the directional dashed-dotted line in FIG. 9) is tilted from the vertical direction. Specifically, for example, as shown in FIG. 9, the configuration may be such that the height of the thin plates (fins) constituting the heat radiation unit 310 becomes smaller with getting closer to the liquid pipe 142. In this configuration, because flowing back of liquid phase refrigerant generated by condensation and liquefaction in the condensation container 121 to the liquid pipe 142 is accelerated by the effect of gravity, efficiency of refrigerant circulation is increased, and accordingly further improvement in the cooling performance can be achieved. Further, as shown in FIG. 10, additional thin plates (fins) 320 may be arranged on the side of the condensation unit 220, which is the opposite side of the heat radiation unit 310. In that case, the wind velocity of a fan to cool the condensation unit 220 can be reduced.

### Fourth Exemplary Embodiment

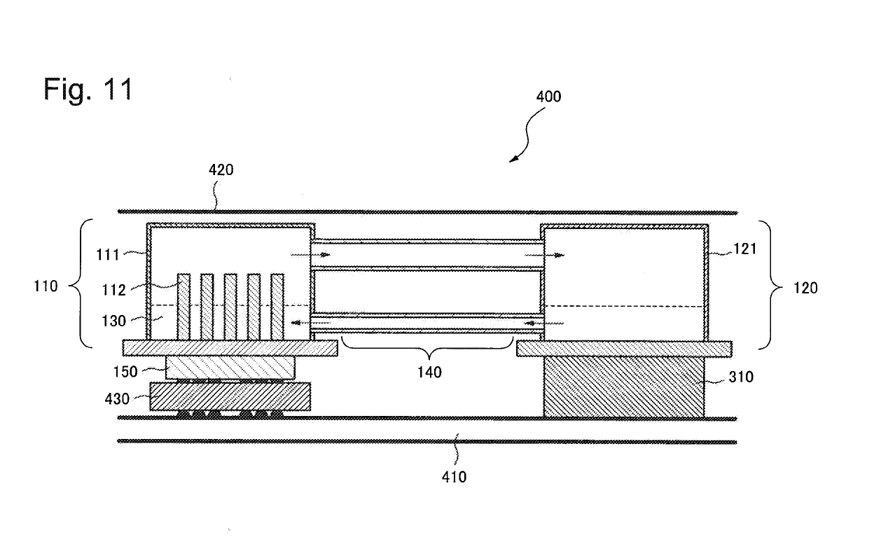

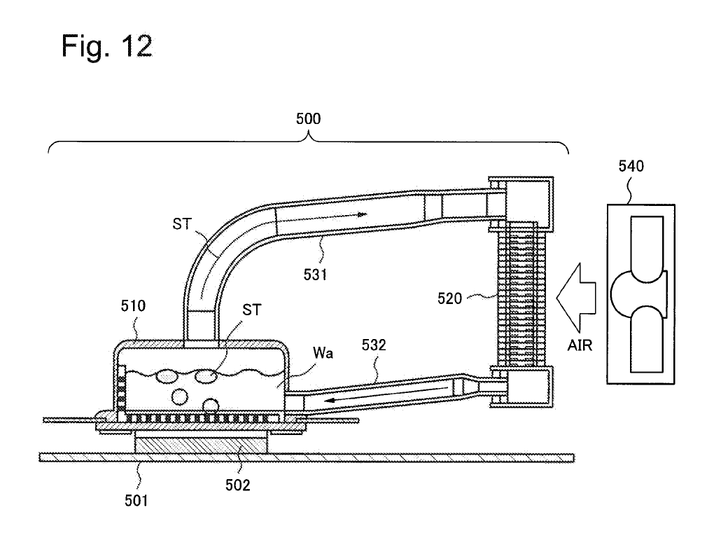

Next, a fourth exemplary embodiment of the present invention will be described. FIG. 11 is a cross-sectional side view showing a configuration of an electronic device 400 according to the fourth exemplary embodiment of the present invention. The electronic device 400 comprises a cooling device, the heat generating body 150 and the heat radiation unit 310. Here, the cooling device has the same configuration as that of the cooling device 100 according to the first exemplary embodiment, and accordingly it includes the evaporation unit 110 which stores the refrigerant 130, the condensation unit 120 which performs heat radiation by condensing and liquefying the vapor-phase refrigerant which was vaporized at the evaporation unit 110, and the piping 140 which connects the evaporation unit 110 with the condensation unit 120. The evaporation unit 110 and the condensation unit 120 are located at approximately the same height in the vertical direction. The evaporation unit 110 comprises an evaporation container 111 and a partition wall section 112 which is arranged within the evaporation container 111 and partitions the refrigerant 130, where the height of the partition wall section 112 is equal to or larger than that of the vapor-liquid interface of the refrigerant 130 and is smaller than that of the evaporation container 111.

When installing the cooling device into a 1 U server, since the inner height of the 1 U server is about 40 mm and the height of a CPU is about 15 mm, the outer height of the evaporation unit 110 is preferred to be about 25 mm. On the other hand, the outer height of the condensation unit 120 is allowed to be up to about 40 mm corresponding to the inner height of a 1 U server. It is more preferable that the outer height of the condensation unit 120 is about 25 mm corresponding to the outer height of the evaporation unit 110 and the outer height of the heat radiation unit 310 is about 15 mm.

In the electronic device 400 according to the present exemplary embodiment, the evaporation unit 110 is arranged to be thermally connected onto the top of the heat generating body 150, and the condensation unit 120 is to be thermally connected onto the top of the heat radiation unit 310.

The electronic device 400 is, for example, a server or the like provided with a central processing unit (CPU) as the heat generating body 150, which is arranged onto a substrate 410 and contained in a housing 420. The heat generating body 150 such as a CPU is mounted on the substrate 410 in a form of being installed in a socket 430 or the like. On the top of the heat generating body 150, the evaporation unit 110 is mounted via a thermal conductive member such as grease, for example. On the other hand, the condensation unit 120 connected with the evaporation unit 110 via the piping 140 is arranged, along with the heat radiation unit 310, at a position separated from the heat generating body 150. Heat generated by the heat generating body 150 is thermally transported by movement of the refrigerant 130 as a vapor-liquid two phase flow, and as a result, the heat generating body 150 is cooled.

As has been described above, according to the electronic device 400 of the present exemplary embodiment, even if the evaporation unit 110 and the condensation unit 120 need to be arranged at approximately the same height in the vertical direction, it is possible to employ a cooling device based on a boiling cooling method having excellent thermal transport capability. Accordingly, even in a case of a low-profile electronic device applicable to a rack with a height of 1 U (44.45 mm), for example, sufficient cooling performance can be achieved.

It is obvious that the present invention is not limited to the exemplary embodiments described above, and various changes and modifications of them are possible within the scope of the invention described in the appended claims, and the changes and modifications also are to be embraced within the scope of the present invention.

This application is based upon and claims the benefit of priority from Japanese Patent Application No. 2011-168396, filed on Aug. 1, 2011, the disclosure of which is incorporated herein in its entirety by reference.

### DESCRIPTION OF THE CODES

100, 200, 300 Cooling device
110 Evaporation unit
111 Evaporation container
112 Partition wall section
120, 220 Condensation unit
121 Condensation container
130 Refrigerant
140 Piping.
141 Vapor pipe
142 Liquid pipe
150 Heat generating body
222 Condensation plate section
310 Heat radiation unit
320 Thin plate (fin)
400 Electronic device
410 Substrate
420 Housing
430 Socket
500 Related boiling cooling unit
501 Circuit board
502 Semiconductor device
510 Evaporation unit
520 Condensation unit
531 Vapor pipe
532 Liquid return pipe
540 Cooling fan

1. A cooling device comprising:
an evaporation unit storing refrigerant;
a condensation unit performing heat radiation by condensing and liquefying vapor-phase refrigerant vaporized at said evaporation unit; and
piping connecting said evaporation unit with said condensation unit;
wherein said evaporation unit comprises an evaporation container and a partition wall section arranged within said evaporation container and constitutes a flow path of said refrigerant; and
the height of said partition wall section is equal to or larger than the height of the vapor-liquid interface of said refrigerant and is smaller than the height of said evaporation container.

2. The cooling device according to claim 1, wherein said evaporation unit and said condensation unit are located at approximately the same height in the vertical direction.

3. The cooling device according to claim 1, wherein
said piping comprises a vapor pipe flowing said vapor-phase refrigerant and a liquid pipe flowing liquid-phase refrigerant generated by condensation and devolatization;
said vapor pipe is connected to said evaporation container at a position of a height equal to or higher than the height of said partition wall section; and
said liquid pipe is connected to said evaporation container at a position of a height equal to or lower than the height of the vapor-liquid interface of said refrigerant.

4. The cooling device according to claim 3, wherein
said liquid pipe is connected to a side surface of said evaporation container; and
said vapor pipe is arranged onto a surface facing said surface to which said liquid pipe of said evaporation container is connected.

5. The cooling device according to claim 3, wherein said liquid pipe is connected to the bottom surface of said evaporation container.

6. The cooling device according to claim 3, wherein,
said refrigerant is contained up to a height equal to or higher than the height of the bottom surface of said liquid pipe opening connected at a higher position of two liquid pipe opening in non-operating state of said cooling device.

7. The cooling device according to claim 1, wherein:
said partition wall section comprises a plurality of partition wall thin plates each of which is a rectangular thin plate standing upright; and
said piping is connected to said evaporation container near an end region of said partition wall thin plates in their longitudinal direction.

8. The cooling device according to claim 1, wherein said partition wall section comprises a plurality of partition wall thin plates each of which sets up a thin plate having side surfaces of a triangular cross section.

9. The cooling device according to claim 1, wherein said partition wall section comprises a plurality of partition wall thin plates each of which sets up a thin plate and having a tapered top end.

10. The cooling device according to claim 5, wherein said plurality of partition wall thin plates are disposed such that their heights become smaller with their getting closer to said vapor pipe.

11. The cooling device according to claim 5, wherein said plurality of partition wall thin plates are disposed such that their lengths become smaller with their getting closer to said vapor pipe.

12. The cooling device according to claim 1, wherein said evaporation container has a cylindrical shape.

13. The cooling device according to claim 1, wherein
said condensation unit comprises a condensation container and a condensation plate section which is disposed within said condensation container and accelerates heat radiation of said vapor-phase refrigerant.

14. The cooling device according to claim 13, wherein
said vapor pipe is connected to said condensation container at a position of a height equal to or higher than the height of said condensation plate section; and
said liquid pipe is connected to said condensation container at a position of a height equal to or lower than the height of the vapor-liquid interface of said refrigerant.

15. The cooling device according to claim 13, wherein
said condensation plate section comprises a plurality of condensation thin plates each of which comprises a rectangular thin plate standing upright; and
said vapor pipe and said liquid pipe are each connected to said condensation container near an end region of said condensation thin plates in their longitudinal direction.

16. The cooling device according to claim 15, wherein
said condensation plate section are disposed such that the longitudinal direction of said condensation thin plates becomes tilted with respect to a direction perpendicular to the vertical direction.

17. The cooling device according to claim 1 further comprising a heat radiation unit connecting with said condensation unit thermally.

18. The cooling device according to claim 17, wherein
said heat radiation unit has a principal surface connecting with said condensation unit thermally, and the normal of said principal surface is tilted from the vertical direction.

19. An electronic device comprising:
a cooling device, a heat generating body and a heat radiation unit, wherein
said cooling device comprises:
an evaporation unit storing refrigerant;
a condensation unit performing heat radiation by condensing and liquefying vapor-phase refrigerant vaporized at said evaporation unit; and
piping connecting said evaporation unit with said condensation unit;
wherein said evaporation unit comprises an evaporation container and a partition wall section arranged within said evaporation container and constitutes a flow path of said refrigerant;
the height of said partition wall section is equal to or larger than the height of the vapor-liquid interface of said refrigerant and is smaller than the height of said evaporation container;
said evaporation unit is disposed to be thermally connected to the top of said heat generating body; and
said condensation unit is disposed to be thermally connected to the top of said heat radiation unit.
